(19) United States
(12) Patent Application Publication
(10) Pub. No.: US 2006/0243977 A1
(43) Pub. Date: Nov. 2, 2006

(54) Electro-optical device, method of manufacturing electro-optical device, and electronic apparatus

(75) Inventor: Yasuji Yamasaki, Chitose-shi (JP)

Correspondence Address: ADVANTEDGE LAW GROUP, LLC, 1928 E. COBBLESTONE RD., SUITE 100, SPRINGVILLE, UT, 84663, US

(73) Assignee: Seiko Epson Corporation, Shinjuku-ku (JP)

(21) Appl. No.: 11/401,007

(22) Filed: Apr. 10, 2006

(30) Foreign Application Priority Data
Apr. 11, 2005 (JP) 2005-113146
Jan. 30, 2006 (JP) 2006-020094

(51) Int. Cl. H01L 29/04

(52) U.S. Cl. 257/59

(57) ABSTRACT

An electro-optical device comprising thin film transistors disposed closer to a substrate than data lines and a first interlayer insulating film that is laminated on the thin film transistors and is subjected to a planarizing process. Storage capacitors are disposed further from the substrate than the data lines, and each storage capacitor includes a fixed potential side electrode, a dielectric film, and a pixel potential side electrode. Pixel electrodes are disposed further from the substrate than the storage capacitors and are electrically connected to the pixel potential side electrode and the thin film transistor. Each of the data lines comprises a conductive light shielding film which is formed so as to at least partially cover the channel region of each of the thin film transistors in plan view.

### RELATED APPLICATION INFORMATION

The present application claims priority from Japanese Patent Application No. 2005-113146, filed on Apr. 11, 2005, and Japanese Patent Application No. 2006-020094, filed on Jan. 30, 2006, the entire contents of which are hereby incorporated by reference.

### BACKGROUND

1. Technical Field

The present invention relates to an electro-optical device, such as a liquid crystal device, to a method of manufacturing an electro-optical device, and to an electronic apparatus, such as a liquid crystal projector.

2. Related Art

In general, an electro-optical device includes pixel electrodes, scanning lines that selectively drive the corresponding pixel electrodes, data lines, and thin-film transistors (TFTs) serving as pixel switching elements, all of which are formed on a substrate. The electro-optical device is constructed such that active matrix driving can be performed. Further, in order to achieve a high contrast ratio, a storage capacitor is provided between a TFT and a pixel electrode. The above-mentioned constituent elements are built in the substrate with high density, and improvement of an opening ratio of a pixel or reduction of the device in size has been contrived (for example, see JP-A-2002-156652).

Recently, electro-optical devices have been required to perform high-quality and high-definition display with a decreased size of device, and thus various measures have been taken. For example, if light is incident on a semiconductor layer of a TFT, a light leak current is generated, and the display quality may be lowered. Therefore, in order to prevent the display quality from being lowered, a light shielding layer may be provided around the semiconductor layer. Preferably, a storage capacitor has as much capacitance as possible. However, a storage capacitor is preferably designed such that the pixel aperture ratio is not sacrificed. Further, these many circuit elements are preferably built on a substrate with high density in order to reduce the size of the device.

Accordingly, various technologies have been suggested in order to obtain desired shapes of electronic elements, such as a storage capacitor or the like, or a method of manufacturing the electronic elements in an electro-optical device, and improving the device performance or manufacturing yield (for example, see JP-A-6-3703, and JP-A-7-49508).

However, according to the various technologies in this field, a laminated structure on the substrate becomes complicated in achieving a high function or a high performance, which results in complicated manufacturing methods and lowering manufacturing yields. In contrast, if the laminated structure on the substrate or manufacturing process is simplified, light shielding performance may be lowered, and accordingly, display quality may be lowered due to light leak current in the semiconductor layer of the TFT.

### SUMMARY

An advantage of one aspect of the invention is that it provides an electro-optical device which is capable of a simplified laminated structure or manufacturing process, and achieving a high-quality display and electronic apparatus having an electro-optical device.

According to one exemplary embodiment of the invention, there is provided an electro-optical device. The electro-optical device includes: a substrate, a plurality of data lines and a plurality of scanning lines that extend so as to cross each other; thin film transistors each of which is disposed lower than the data line on the substrate; first interlayer insulating films that are laminated on the thin film transistors and that are subjected to a planarizing process; storage capacitors each of which is disposed on a region including a region opposite to a channel region of the thin film transistor on the substrate in plan view and disposed higher than the data line, and each of which has a structure in which a fixed potential side electrode, a dielectric film, and a pixel potential side electrode are sequentially laminated from the bottom; and pixel electrodes each of which is disposed for each pixel provided so as to correspond to the data line and the scanning line on the substrate in plan view, disposed higher than the storage capacitor, and electrically connected to the pixel potential side electrode and the thin film transistor. Further, each of the data lines is composed of a conductive light shielding film and formed in a region that includes a region to cover the channel region on the substrate in plan view.

According to this embodiment, at the time of operation, the thin film transistor applies the data signal from the data line to the pixel electrode corresponding to the location of the pixel selected by the scanning line, which it allows the driving of the active matrix. The potential holding characteristic in the pixel electrode is improved by the storage capacitor, which results in a high contrast ratio in the display. In addition, in the storage capacitor, the fixed potential side electrode, the dielectric film, and the pixel potential side electrode may be sequentially laminated from the bottom, or may be laminated in reverse order.

Since the data line is formed on the first interlayer insulating film which has been subjected to a planarizing process, a portion of the data line which covers the channel region, that is, a portion for shielding the channel region form the light is also planarized. Accordingly, on the side of the data line opposite of the channel region, diffused reflection or light scattering generated due to return light or oblique light is reduced. Further, on the side opposite of the side of the data line that faces the channel region, diffused reflection or light scattering generated due to incident light is reduced. In addition, the data line shields light at a laminated location relatively close to the thin film transistor, through the first interlayer insulating film which is subjected to a planarizing process and formed so as to have a relatively small thickness. Accordingly, the ability to shield the thin film transistor from oblique light contained in incident light by, for example, about several tens of percent, or diffusely reflective light reflected on another portion in the electro-optical device or stray light, may become larger in accordance with the distance from the data line to the thin film transistor. Therefore, as described above, at the time of operation, the light leak current in the thin film transistor is reduced so that it is possible to improve the contrast ratio, which results in an image display of high quality.

Further, since the first interlayer insulating film relatively close to the substrate is subjected to a planarizing process, external waviness or step, that is, a global step, which occurs on the substrate due to the density or unevenness, can be reduced. For example, when the electro-optical material, such as the liquid crystal, is interposed between the substrate having the above-mentioned laminated structure and the counter substrate opposite to the corresponding substrate, since the surface of the substrate becomes flat without a global step, it is possible to reduce disorder from occurring in an alignment state of the electro-optical material, which results in a display of higher quality. If the global step occurs, contrast irregularities or luminance irregularities occur between the region near the center and the peripheral region in the image display region due to the global step. However, according to an exemplary aspect of the invention, this phenomenon can be reduced or prevented in advance.

In addition, as described above, the light leak current can be resolved by a relatively simple structure of a base substrate like the data line being formed on the first interlayer insulating film which has been subjected to a planarizing process. Therefore, it is possible to simplify the laminated structure on the substrate, so that the manufacturing process can be simplified and the manufacturing yield improved.

In another exemplary embodiment of the invention, the first interlayer insulating film is subjected to a CMP (chemical mechanical polishing) process that serves as the planarizing process.

According to this embodiment of the invention, the surface of the first interlayer insulating film can be planarized while improving the smoothness of the surface of the first interlayer insulating film by means of a CMP process. Therefore, on the side of the data line which faces the channel region, diffused reflection or light scattering generated due to return light or oblique light can be reduced. In addition, on the side opposite of the side of the data line which faces the channel region, diffused reflection or light scattering generated due to incident light can be reduced.

In an exemplary embodiment, the first interlayer insulating film contains a first fluidization material that fluidizes at a predetermined temperature, and the first interlayer insulating film is subjected to, as the planarizing process, a fluidization process for fluidizing the first fluidization material.

According to this exemplary embodiment, when the first interlayer insulating film contains the first fluidization material, such as, for example, borophosphosilicateglass (hereinafter, simply referred to as “BPSG”) that fluidizes at a predetermined temperature, the first interlayer insulating film can be planarized by the reflow. Accordingly, on the side of the data line which faces the channel region, diffused reflection or light scattering generated due to return light or oblique light can be reduced. In addition, on the side opposite of the side of the data line which faces the channel region, diffused reflection or light scattering generated due to incident light can be reduced.

In another exemplary embodiment of the invention, another interlayer insulating film, which has been subjected to the planarizing process, is laminated on at least one location among layers of the data line, the storage capacitor, and the pixel electrode on the substrate.

According to this embodiment, on the substrate, the data line, the storage capacitor, and the pixel electrode are laminated through the other interlayer insulating film. The unevenness occurs on the surface of the other interlayer insulating film right after the lamination, due to the elements of the lower layer side. Accordingly, if the unevenness is removed by means of a planarizing process, such as, for example, a CMP process, a polishing process, a spin coating process, a concave portion burying process, or the like, the surface of the interlayer insulating film can be planarized. For example, when the electro-optical material, such as the liquid crystal, is interposed between the substrate having the above-mentioned laminated structure and the counter substrate opposite to the corresponding substrate, since the surface of the substrate becomes flat, it is possible to reduce disorder from occurring in an alignment state of the electro-optical material, which results in a display of a higher quality. In addition, this planarizing process may be preferably performed on the entire surface of the interlayer insulating film, but even if the planarizing process is performed on the surface of any interlayer insulating film, the surface of the substrate becomes flat to some extent, as compared with the case in which the planarizing process is performed on the entire surface of the interlayer insulating film. Therefore, it is possible to reduce the disorder from occurring in the alignment state of the electro-optical material.

In still another exemplary embodiment of the invention, each of the data lines includes: a main body portion that is a part of the conductive light shielding film; and a low-reflective portion that is the other portion of the conductive light shielding film and formed on a side of the main body portion opposite of the channel region (i.e. facing the channel region), and that has a lower reflectance than the main body portion.

According to this embodiment, since the low-reflective portion is formed, it is possible to prevent the reflection of the back surface of the substrate on the surface of the data line opposite of the channel region, that is, the surface of the data line at the lower layer side, or reflection of the return light like light which is emitted from another electro-optical device such as a double-plate-type projector or the like and then passes through a synthesis optical system. Therefore, it is possible to reduce the influence of light on the channel region. In addition, as the low-reflective portion, metal of a material whose reflectance is lower than that of an Al film constituting the main body portion of the data line, or barrier metal may be formed.

In still another exemplary embodiment of the invention, each of the data lines includes: a main body portion that is a portion of the conductive light shielding film; a lower low-reflective portion that is another portion of the conductive light shielding film and formed on a side of the main body portion opposite of the channel region (i.e. facing the channel region), and that has lower reflectance than the main body portion; and an upper low-reflective portion that is the other portion of the conductive light shielding film and formed on a side opposite to the side of the main body portion opposite to the channel region (i.e. facing away from the channel region), and that has lower reflectance than the main body portion.

According to this embodiment, since the lower low-reflective portion is formed, it is possible to prevent the reflection of the back surface of the substrate on the surface of the data line opposite to the channel region, that is, the surface of the data line at the lower layer side, or reflection of the return light which is emitted from another electro-optical device such as a double-plate-type projector or the like and then passes through an synthesis optical system. In addition, since the upper reflective portion is formed, it is possible to prevent the diffused reflection or light scattering from being generated due to the incident light, on the surface of the side opposite of the side of the data line opposite to the channel region, that is, the surface of the data line at the upper layer side. Accordingly, it is possible to reduce the influence of light on the channel region. In addition, as the lower low-reflective portion and the upper low-reflective portion, metal of a material whose reflectance is lower than that of an Al film constituting the main body portion of the data line, or barrier metal may be formed.

In still another exemplary embodiment of the invention, the above-mentioned electro-optical device further includes: a lower light shielding film that is disposed lower than the thin film transistor on the substrate; and a base insulating film that is laminated on the lower light shielding film and subjected to a planarizing process.

According to this embodiment, since the thin film transistor, the scanning line, and the first interlayer insulating film are laminated on the base insulating film which has been subjected to the planarizing process, the uniformity is small on the surface of the first interlayer insulating film before performing the planarizing process, as compared with the case in which the base insulating film is not subjected to the planarizing process. For this reason, it is possible to easily planarize the first interlayer insulating film.

In the exemplary embodiment in which the planarizing process is performed on the base insulating film, preferably, the base insulating film may be subjected to a CMP process which serves as the planarizing process.

In this case, the surface of the base insulating film can be planarized while improving the smoothness of the surface of the base insulating film by means of the CMP process. For this reason, it is possible to easily planarize the first interlayer insulating film.

In the exemplary embodiment in which the planarizing process is performed on the above-mentioned base insulating film, preferably, the base insulating film may contain a second fluidization material that fluidizes at a predetermined temperature, and the base insulating film may be subjected to, as the planarizing process, a fluidization process for fluidizing the second fluidization material.

In this case, when the base insulating film contains the second fluidization material, such as, for example, BPSG or the like, that fluidizes at a predetermined temperature, the base insulating film can be planarized by the reflow. For this reason, it is possible to easily planarize the first interlayer insulating film.

According to still another exemplary embodiment of the invention, there is provided an electronic apparatus which includes the above-mentioned electro-optical device. The electronic apparatus according to this embodiment can be applied to various electronic apparatuses, such as the electronic apparatuses capable of achieving high quality image display such as a television, a cellular phone, a word processor, a view-finder-type or monitor-direct-view video tape recorder, a workstation, a video phone, a POS terminal, a printer using as an exposure head a further electro-optical device such as a touch panel or the like, an image forming apparatus, such as a copy machine and a facsimile, or the like. Further, examples of the electronic apparatus according to this embodiment of the invention may include an electrophoresis device, such as an electronic paper or the like, and an electron emission device (field emission display and conduction electron-emitter display).

According to still another exemplary embodiment of the invention, there is provided a method of manufacturing an electro-optical device, the electro-optical device including, on a substrate, a plurality of data lines and a plurality of scanning lines that extend so as to cross each other; top-gate-type thin film transistors each of which is disposed lower than the data line with a first interlayer insulating film interposed therebetween; storage capacitors each of which is disposed higher than the data line, and pixel electrodes each of which is disposed higher than the storage capacitor. The method includes: forming the thin film transistor such that a channel region of the thin film transistor is covered with the data line in a region corresponding to an intersection between the data line and the scanning line on the substrate in plan view; forming the first interlayer insulating film on the thin film transistor; subjecting the first interlayer insulating film to a planarizing process; forming the data line composed of a conductive light shielding film on the first interlayer insulating film; forming the storage capacitor in a region including a region opposite to a channel region of the thin film transistor on the substrate in plan view, such that a fixed potential side electrode, a dielectric film, and a pixel potential side electrode are sequentially laminated on the data line; and forming the pixel electrode on the storage capacitor for each pixel provided so as to correspond to the data line and the scanning line on the substrate in plan view, such that the pixel electrode is electrically connected to the thin film transistor and the pixel potential side electrode.

According to this exemplary embodiment, the above-mentioned electro-optical device can be manufactured. In particular, since the data line composed of the conductive light shielding film is formed on the first interlayer insulating film which has been subjected to the planarizing process, the light leak current in the thin film transistor can be reduced, so that the contrast ratio can be improved, which results in a high quality image display. Further, since the laminated structure on the substrate is relatively simple, the manufacturing process can be simplified, so that the manufacturing yield can be improved. Furthermore, in the process of manufacturing the storage capacitor, the fixed potential side electrode, the dielectric film, and the pixel potential side electrode may be sequentially laminated in this order or may be laminated in reverse order.

### BRIEF DESCRIPTION OF THE DRAWINGS

The invention will be described with reference to the accompanying drawings, wherein like numbers reference like elements, and wherein:

FIG. 1 is a plan view illustrating an entire structure of a liquid crystal device according to a first exemplary embodiment of the invention.

FIG. 2 is a cross-sectional view taken along the line II-II of FIG. 1.

FIG. 3 is an equivalent circuit diagram of various elements, wiring lines, or the like in a plurality of pixels.

FIG. 4 is a plan view of a pixel group on a TFT array substrate according to the first exemplary embodiment of the invention, which illustrates a structure of only lower layer portions (lower layer portions by the reference numeral 6a (data line) in FIG. 7).

FIG. 5 is a plan view of a pixel group on a TFT array substrate according to the first exemplary embodiment of the invention, which illustrates a structure of only upper layer portions (upper layer portions exceeding the reference numeral 6a (data line) in FIG. 7).

FIG. 6 is a plan view when FIGS. 4 and 5 overlap, which illustrates an enlarged part.

FIG. 7 is a cross-sectional view taken along the line VII-VII when FIGS. 4 and 5 overlap.

FIG. 8 is a cross-sectional view illustrating a structure of a data line according to another exemplary embodiment of the invention.

FIG. 9 is a cross-sectional view illustrating a structure of a data line according to yet another exemplary embodiment of the invention, which is similar to FIG. 8.

FIG. 10 is a first cross-sectional view sequentially illustrating manufacturing processes of a liquid crystal device according to the first exemplary embodiment of the invention.

FIG. 11 is a second cross-sectional view sequentially illustrating manufacturing processes of a liquid crystal device according to the first exemplary embodiment of the invention.

FIG. 12 is a third cross-sectional view sequentially illustrating manufacturing processes of a liquid crystal device according to the first exemplary embodiment of the invention.

FIG. 13 is a fourth cross-sectional view sequentially illustrating manufacturing processes of a liquid crystal device according to the first exemplary embodiment of the invention.

FIG. 14 is a plan view illustrating a structure of a projector as an example of yet another exemplary embodiment of the invention to which an electro-optical device is applied.

FIG. 15 is a perspective view illustrating a structure of a personal computer as an example of yet another exemplary embodiment of the invention to which an electro-optical device is applied.

FIG. 16 is a perspective view illustrating a structure of a cellular phone which is an example of an another embodiment of the invention to which an electro-optical device is applied.

### DESCRIPTION OF EXEMPLARY EMBODIMENTS

Hereinafter, preferred embodiments of the invention will be described in detail with reference to accompanying drawings. In the exemplary embodiments which will be described in detail below, a driving circuit-built TFT active-matrix-driving-type liquid crystal device, which is an example of an electro-optical device according to one embodiment of the invention, will be exemplified.

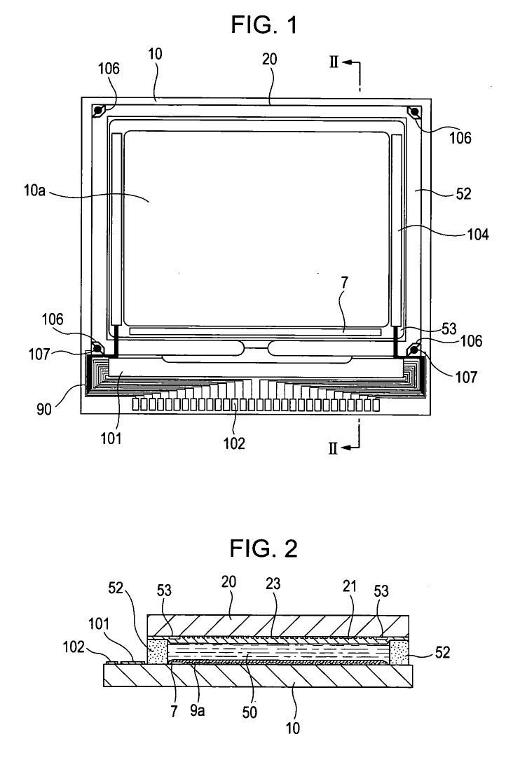

A liquid crystal device according to a first exemplary embodiment of the invention will be described in detail with reference to FIGS. 1 to 9.

Structure of Electro-Optical Device

First, the structure of a liquid crystal device according to the an exemplary embodiment will be described with reference to FIGS. 1 and 2. FIG. 1 is a plan view illustrating a structure of the liquid crystal device according to the an embodiment of the invention, and FIG. 2 is a cross-sectional view taken along the line II-II of FIG. 1.

In FIGS. 1 and 2, in the liquid crystal device according to one embodiment, a TFT array substrate 10 and a counter substrate 20 are disposed so as to be opposite to each other. Further, a liquid crystal layer 50 is sealed between the TFT array substrate 10 and the counter substrate 20. Furthermore, the TFT array substrate 10 and the counter substrate 20 are bonded to each other by means of a sealant 52, which is provided in a sealing region located around an image display region 10a.

In FIG. 1, in parallel to the inner side of the sealing region where the sealant 52 is disposed, a frame light-shielding film 53, having a light-shielding property, which defines a frame region of the image display region 10a, is provided on the side of the counter substrate 20. In a portion of a peripheral region, which is located at an outer side of the sealing region where the sealant 52 is disposed, a data line driving circuit 101 and external circuit connecting terminals 102 are provided along one side of the TFT array substrate 10. On an inner side than the sealing region which is provided along the one side, a sampling circuit 7 is provided so as to be covered with the frame light-shielding film 53. Further, on inner sides of sealing regions which are provided along two sides adjacent to the one side, two scanning line driving circuits 104 are provided so as to be covered with the frame light-shielding film 53. Furthermore, on regions of the TFT array substrate 10 which are opposite to four corners of the counter substrate 20, upper and lower conductive terminals 106 are disposed for connecting both substrates by means of upper and lower conductive members 107, which results in electrical connection between the TFT array substrate 10 and the counter substrate 20.

On the TFT array substrate 10, wiring lines 90 are provided for electrically connecting the external circuit connecting terminals 102, the data line driving circuit 101, the scanning line driving circuits 104, the upper and lower conductive terminals 106, or the like.

In FIG. 2, a laminated structure, in which pixel switching TFTs (thin film transistors) serving as driving elements or wiring lines such as scanning lines, data lines, or the like are incorporated, is formed on the TFT array substrate 10. In the image display region 10a, pixel electrodes 9a are provided on the pixel switching TFTs or the wiring lines, such as the scanning lines, the data lines, or the like. In addition, on a surface of the counter substrate 20 which is opposite to the TFT array substrate 10, a light-shielding film 23 is formed. In addition, on the light-shielding film 23, a counter electrode 21, which is made of a transparent material, such as ITO or the like, is formed so as to be opposite to the plurality of pixel electrodes 9a.

Further, in addition to the data line driving circuit 101 and the scanning line driving circuits 104, a test circuit, which tests a quality, a defect, or the like of the corresponding liquid crystal device during manufacturing process or at the time of shipment, a testing pattern, or the like may be formed on the TFT array substrate 10.

Structure of Image Display Region

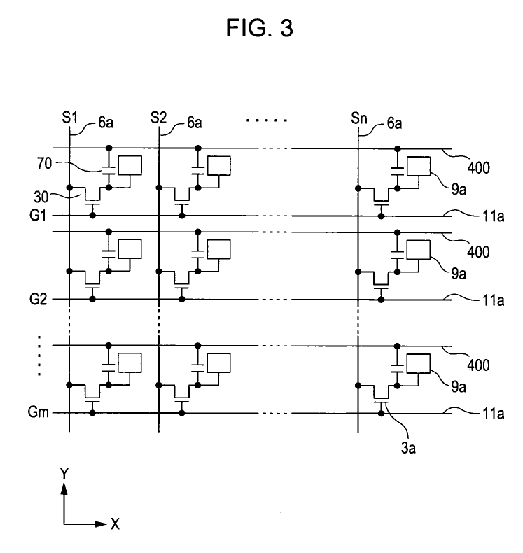

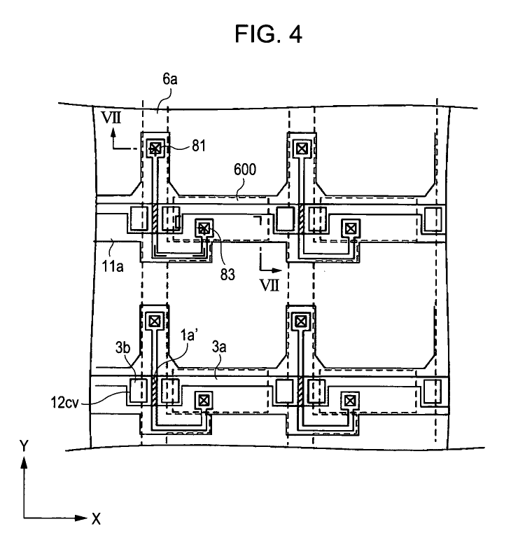

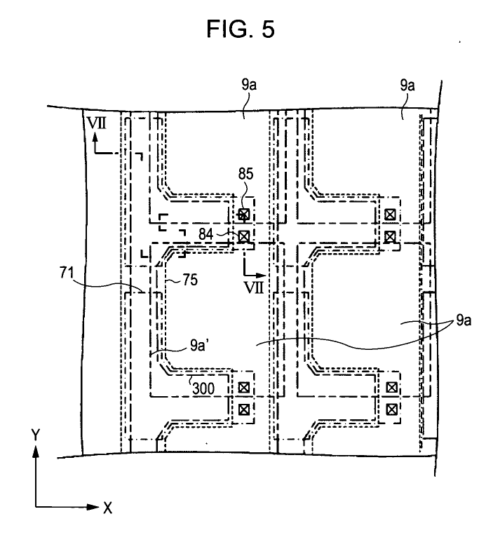

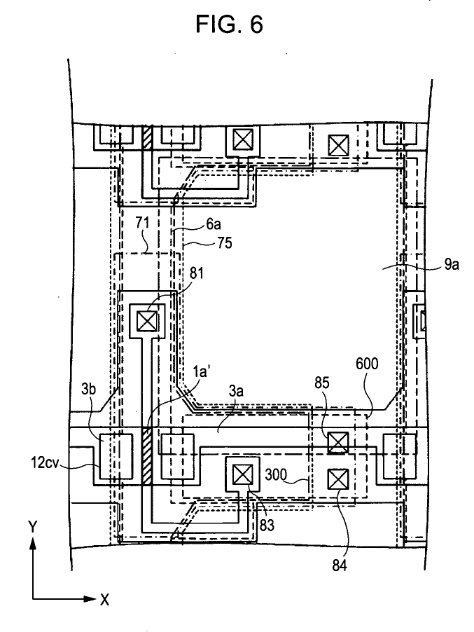

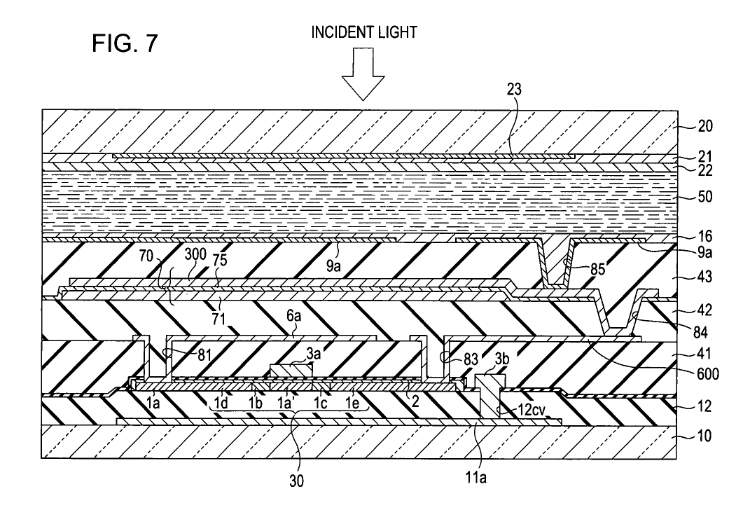

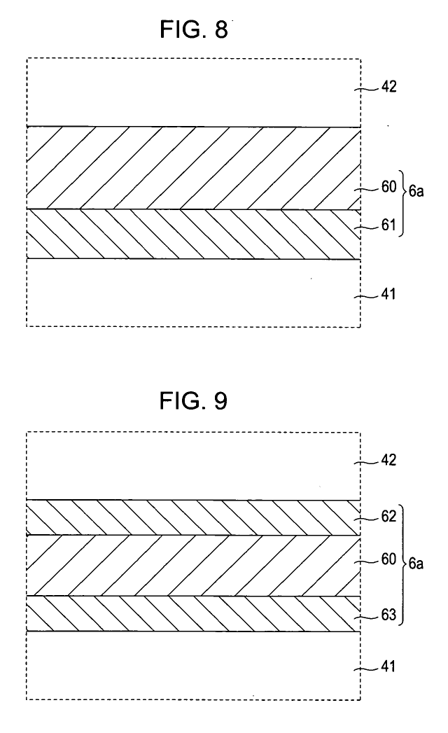

Next, a structure of a pixel portion of the liquid crystal device according to an exemplary embodiment of the invention will be described with reference to FIGS. 3 to 9. FIG. 3 is an equivalent circuit diagram of various elements, wiring lines, or the like in a plurality of pixels, which are disposed in a matrix so as to form an image display region of the liquid crystal device. FIGS. 4 to 6 are plan views illustrating a partial structure of pixel portions formed on the TFT array substrate in the liquid crystal device according to a first exemplary embodiment of the invention. FIGS. 4 and 5 are diagrams illustrating lower layer portions (FIG. 4) and upper layer portions (FIG. 5) in a laminated structure, respectively, which will be described in detail below. FIG. 6 is a plan view when FIGS. 4 and 5 overlap, which illustrates an enlargement of a laminated structure. FIG. 7 is a cross-sectional view taken along the line VII-VII when FIGS. 4 and 5 overlap. FIG. 8 is a cross-sectional view illustrating a structure of a data line according to another exemplary embodiment of the invention. FIG. 9 is a cross-sectional view illustrating a structure of a data line according to yet another exemplary embodiment of the invention, which is similar to FIG. 8. In FIGS. 7 to 9, the scale of each layer or member has been adjusted in order to have a recognizable size in the drawings.

Structure of Pixel Portion

As shown FIG. 3, in each of the plurality of pixels which are disposed in a matrix so as to form the image display region of the liquid crystal device according to the present embodiment, a pixel electrode 9a and a TFT 30 for controlling the switching operation of the pixel electrode 9a are formed, and the data line 6a, which is supplied with an image signal, is electrically connected to a source of the corresponding TFT 30. The image signals S1, S2, . . . , and Sn, which are written in the data lines 6a, may be sequentially supplied in this order, and may be supplied for each group of a plurality of adjacent data lines 6a.

In addition, the scanning line 11a is electrically connected to a gate of the TFT 30, and the scanning signals G1, G2, . . . , and Gm are line-sequentially applied to the respective scanning lines 11a with a predetermined timing in a pulsed manner. The pixel electrode 9a is electrically connected to a drain of the TFT 30, and closes a switch of the TFT 30 serving as a switching element for a predetermined period such that the image signals S1, S2, . . . , and Sn supplied from the data lines 6a are written with a predetermined timing.

The image signals S1, S2, . . . , and Sn of predetermined levels, which are written in liquid crystal being an example of an electro-optical material through the pixel electrodes 9a, are held for a predetermined period between the counter electrode formed on the counter substrate and the pixel electrodes. Alignment or order of a molecular aggregate of the liquid crystal varies in accordance with an applied voltage level, so that the liquid crystal modulates light, thereby allowing gray-scale display to be performed. In a normally white mode, transmittance with respect to incident light is decreased in accordance with a voltage applied for each pixel, and in a normally black mode, transmittance with respect to incident light is increased in accordance with a voltage applied for each pixel. As a whole, light having contrast according to the image signal is emitted from the liquid crystal device.

In order to prevent the held image signal from being leaked, a storage capacitor 70 is additionally provided in parallel to the liquid crystal capacitor which is formed between the pixel electrode 9a and the counter electrode. One electrode of the storage capacitor 70 is connected to a drain of the TFT 30 in parallel to the pixel electrode 9a, and the other electrode of the storage capacitor 70 is connected to a capacitor wiring line 400 with a fixed potential so as to have a constant potential.

Structure of Pixel Portion

Next, a structure of the pixel portion for achieving the above-mentioned operation will be described with reference to FIGS. 4 to 9.

In FIGS. 4 to 9, the respective circuit elements of the above-mentioned pixel portion are patterned, and then constructed on the TFT array substrate 10 as the laminated conductive films. The TFT array substrate 10 is composed of any one of, for example, a glass substrate, a quartz substrate, an SOI substrate, a semiconductor substrate, or the like, and it is disposed so as to be opposite to the counter substrate 20 composed of the glass substrate or the quartz substrate. The respective circuit elements are composed of five layers, sequentially formed from the bottom, which include a first layer including the scanning line 11a, a second layer including the TFT 30 or the like, a third layer including the data line 6a or the like, a fourth layer including the storage capacitor 70 or the like, and a fifth layer including the pixel electrode 9a or the like. In addition, a base insulating film 12 is provided between the first layer and the second layer, a first interlayer insulating film 41 is provided between the second layer and the third layer, a second interlayer insulating film 42 is provided between the third layer and the fourth layer, and a third interlayer insulating film 43 is provided between the fourth layer and the fifth layer. As a result, the respective circuit elements are prevented from being short-circuited among them. Further, among the five layers, the first to third layers are shown in FIG. 4 as lower layer portions, and the fourth and fifth layers are shown in FIG. 5 as upper layer portions.

Structure of First Layer—Scanning Line

The first layer is formed of the scanning lines 11a. Each of the scanning lines 11a is patterned in a shape that includes a main line portion extending in an X direction of FIG. 4 and protruding portions extending in a Y direction of FIG. 4 where the data line 6a extends. This scanning line 11a is made of, for example, conductive polysilicon. In addition to the conductive polysilicon, the scanning line 11a may be made of elemental metal containing at least one of high-melting metals, such as titan (Ti), chrome (Cr), tungsten (W), tantalum (Ta), molybdenum (Mo), or the like, an alloy, metal silicide, polysilicide, or a laminator thereof.

Structure of Second Layer—TFT

The second layer is formed of the TFTs 30. Each of the TFTs 30 has, for example, an LDD (lightly doped drain) structure, and includes a gate electrode 3a, a semiconductor layer 1a, and an insulating film 2 that includes a gate insulating film for insulating the gate electrode 3a and the semiconductor layer 1a. The gate electrode 3a is formed of, for example, conductive polysilicon. The semiconductor layer 1a is formed of, for example, polysilicon, and includes a channel region 1a′, a lightly doped source region 1b, a lightly doped drain region 1c, a highly doped source region 1d, and a highly doped drain region 1e. In this case, preferably, the TFT 30 has an LDD structure. However, the TFT 30 may have an offset structure in which impurities are not implanted in the lightly doped source region 1b and the lightly doped drain region 1c, or a self-aligned structure in which a highly doped source region and a highly doped drain region are formed by using the gate electrode 3a as a mask and implanting impurities at a high concentration.

In a portion 3b of the gate electrode 3a of the TFT 30, the gate electrode 3a is electrically connected to the scanning line 11a through a contact hole 12cv which is formed in the base insulating film 12.

The base insulating film 12 is made of, for example, a silicon oxide film, which is an example of “a second fluidization material” according to an exemplary embodiment of the present embodiment. In addition to an interlayer insulating function between the first and second layers, the base insulating film 12 is formed on the entire surface of the TFT array substrate 10, so that it is possible to prevent an element characteristic of the TFT 30 from varying due to the roughness or contamination caused by the polishing of the substrate surface. In this case, as a modification of the present embodiment, the base insulating film 12 may be subjected to a planarizing process. That is, for example, a fluidization process may be carried out for heating the base insulating film 12 to fluidify it, that is, for melting (reflowing) the base insulating film 12. In this case, an unevenness portion due to the scanning line 11a or the like, which is formed below the base insulating film 12, is not preferably formed on a surface of the first interlayer insulating film 41 (which will be described in detail below) which is laminated on the base insulating film 12. Therefore, it is possible to easily planarize the first interlayer insulating film 41. As such a planarizing process, a CMP process may be performed on the surface of the base insulating film 12.

In addition, the TFT 30 according to the present embodiment is a top gate type; however, in another embodiment of the invention, it may be a bottom gate type.

Structure of Third Layer—Data Line

The third layer has the data line 6a and a relay layer 600.

The data line 6a has a three-layered structure which has an aluminum layer, a titan nitride layer, and a silicon nitride layer sequentially provided from the bottom, which is an example of “a conductive light shielding film” according to one exemplary embodiment of the invention. The data line 6a is formed so as to partially cover the channel region 1a′ of the TFT 30. For this reason, it is possible to shield the channel region 1a′ of the TFT 30 with respect to incident light from the top layer side, by means of the data line 6a which can be disposed so as to be adjacent to the channel region 1a′. In addition, the data line 6a can be electrically connected to the highly doped source region 1d of the TFT 30 through a contact hole 81 passing through the first interlayer insulating film 41. The first interlayer insulating film 41 is made of, for example, silicate glass, such as NSG (non-silicate glass), PSG (phosphosilicate glass), BSG (boronsilicate glass), BPSG (borophosphosilicate glass), or the like, silicon nitride or silicon oxide, which is an example of “a first fluidization material” according to one exemplary embodiment of the invention, and a planarizing process is performed for the first interlayer insulating film 41. That is, as an example of “the planarizing process” according to an embodiment of the invention, a fluidization process may be carried out for heating, for example, the first interlayer insulating film 41 so as to be fluidized, that is, for melting (reflowing) the first interlayer insulating film 41. Alternatively, as this planarizing process, a CMP process may be performed on the surface of the first interlayer insulating film 41. In addition, the planarizing process may be performed by forming the planarizing film by means of a spin coating method, or the planarizing process may be performed by partially burying an insulating film, located below the first interlayer insulating film 41 which becomes a convex portion when no planarizing process is performed, or the first interlayer insulating film 41, which becomes the convex portion by providing the concave portion in the TFT array substrate 10, in the corresponding concave portion so as not to become the convex portion.

In an exemplary embodiment of the invention, the data line 6a is formed on the first interlayer insulating film 41 where the planarizing process is performed. Therefore, a portion of the data line 6a which covers the channel region 1a′, that is, a portion of the data line 6a which shields the channel region 1a′ from the light is also subjected to the planarizing process. Therefore, on the side of the data line 6a which faces the channel region 1a′ (that is, a lower side in FIG. 7), diffused reflection or light scattering generated due to return light or oblique light is reduced. On the side opposite to the side of the data line 6a which faces the channel region 1a′ (that is, an upper side in FIG. 7), diffused reflection or light scattering generated due to incident light is reduced.

In addition, the data line 6a shields light at a laminated location relatively close to the TFT 30, through the first interlayer insulating film 41 which is subjected to a planarizing process and formed so as to have a relatively small thickness. For this reason, its ability to shield the TFT 30 from oblique light contained in incident light by, for example, about several tens of percent or diffusely reflective light reflected on another portion in the liquid crystal device or stray light, becomes larger in accordance with the distance from the data line 6a to the TFT 30. Therefore, a light leak current in the TFT 30 is reduced, so that it is possible to improve the contrast ratio.

Further, since the first interlayer insulating film 41 relatively close to the TFT array substrate 10 is subjected to a planarizing process, external waviness or step, which occurs on the TFT array substrate 10 due to the density of unevenness, that is, a global step can be reduced. Accordingly, since the surface of the TFT array substrate 10 becomes flat without a global step, it is possible to reduce disorder from occurring in an alignment state of the liquid crystal layer 50. That is, it is possible to reduce or prevent contrast irregularities or luminance irregularities from occurring between the region near the center and the peripheral region in the image display region 10a (see FIG. 1) due to the global step.

FIG. 8 illustrates another exemplary embodiment of the present embodiment. As shown in FIG. 8, the data line 6a may have a main body portion 60 and a low-reflective portion 61. In this case, the main body portion 60 is made of, for example, an Al film or the like. The reflective portion 61 is formed at a side (lower side in FIG. 8) of the main body portion 60 opposite to the channel region 1a′ (see FIG. 7), and it is made of metal of a material whose reflectance is smaller than that of the main body portion 60, or barrier metal. Therefore, it is possible to prevent the reflection of the back surface of the TFT array substrate 10 (see FIG. 7) on the surface of the side of the data line 6a opposite to the channel region 1a′ (that is, lower surface in FIG. 8) or reflection of the return light like the light which is emitted from another electro-optical device such as a double-plate-type projector and then passes through an synthesis optical system. Therefore, it is possible to reduce the influence of light on the channel region 1a′. In addition, chrome (Cr), titan (Ti), titan nitride (TiN), tungsten (W), or the like may be used as metal of a material whose reflectance is smaller than that of an Al film, or barrier metal.

FIG. 9 illustrates yet another exemplary embodiment of the present embodiment. As shown in FIG. 9, the data line 6a may have a main body portion 60, a lower low-reflective portion 63, and an upper low-reflective portion 62. The main body portion 60 is made of, for example, an Al film or the like. The lower low-reflective portion 63 is formed on a side (lower side in FIG. 9) of the main body portion 60 opposite to the channel region 1a′ (see FIG. 7), and it is made of metal of a material whose reflectance is smaller than that of the main body portion 60, or barrier metal. In addition, the upper low-reflective portion 62 is formed on a side (upper side in FIG. 9) opposite to the side of the main body portion 60 opposite to the channel region 1a′ (see FIG. 7), and it is made of metal of a material whose reflectance is smaller than that of the main body portion 60, or barrier metal.

Accordingly, it is possible to prevent, by means of the lower low-reflective portion 63, the reflection of the back surface of the TFT array substrate 10 (see FIG. 7) on the surface of the side of the data line 6a opposite to the channel region 1a′ (that is, lower surface in FIG. 9) or reflection of the return light like the light which is emitted from another electro-optical device such as a double-plate-type projector and then passes through a synthesis optical system. Further, it is possible to prevent the diffused reflection or light scattering from occurring on the surface of the side opposite to the side of the data line 6a opposite to the channel region 1a′ (that is, upper surface in FIG. 9) due to the incident light, by means of the upper reflective portion 61. Therefore, it is possible to reduce the influence of light on the channel region 1a′. In addition, chrome (Cr), titan (Ti), titan nitride (TiN), tungsten (W), or the like may be used as metal of a material whose reflectance is smaller than that of an Al film, or barrier metal.

The relay layer 600 is formed of the same film as the data line 6a. As shown in FIG. 4, the relay layer 600 and the data line 6a are formed such that they are separated from each other. In addition, the relay layer 600 is electrically connected to the highly doped drain region 1e of the TFT 30 through a contact hole 83 which passes trough the first interlayer insulating film 41.

Structure of Fourth Layer—Storage

The fourth layer is formed of the storage capacitors 70. Each of the storage capacitors 70 has a structure in which a capacitor electrode 300 and a lower electrode 71 are disposed so as to be opposite to each other through a dielectric film 75. In this embodiment, the capacitor electrode 300 is an example of “a pixel potential side electrode”, and the lower electrode 71 is an example of “a fixed potential side electrode”. An extending portion of the capacitor electrode 300 is electrically connected to the relay layer 600 through a contact hole 84 which passes through the second interlayer insulating film 42.

The capacitor electrode 300 or the lower electrode 71 is made of elemental metal containing at least one of high-melting metals, such as, for example, Ti, Cr, W, Ta, Mo, or the like, an alloy, metal silicide, polysilicide, or a laminator thereof. Preferably, the capacitor electrode 300 or the lower electrode 71 is made of tungsten silicide.

As shown in FIG. 5, the dielectric film 75 is formed in a non-opening region located in a gap of an opening region for each pixel on the TFT array substrate 10 in plan view. That is, the dielectric film 75 is seldom formed in the opening region. Therefore, even though the dielectric film 75 is made of a non-transparent film, the transmittance of the opening region is not lowered. Accordingly, the dielectric film 75 is made of a silicon nitride film having a high dielectric constant without considering the transmittance. Further, in addition to the silicon nitride film, a single-layered film, such as hafnium oxide (HfO₂), aluminum oxide (Al₂O₃), tantalum oxide (Ta₂O₅), or the like, or a multilayered film may be used as the dielectric film.

The second interlayer insulating film 42 is formed of, for example, NSG. In addition, in the second interlayer insulating film 42, silicate glass, such as PSG, BSG, BPSG, or the like, silicon nitride or silicon oxide may be used. The surface of the second interlayer insulating film 42 is subjected to a planarizing process, such as a CMP process, a polishing process, a spin coating process, a concave portion burying process, or the like. Therefore, unevenness portions of the lower layer side due to these elements are removed, and the surface of the second interlayer insulating film 42 is planarized. Therefore, it is possible to reduce the disorder from occurring in an alignment state of the liquid crystal layer 50 interposed between the TFT array substrate 10 and the counter substrate 20, which results in high definition display.

Structure of Fifth Layer—Pixel Electrode

A third interlayer insulating film 43 is formed on an entire surface of the fourth layer, and the pixel electrode 9a serving as the fifth layer is formed on the third interlayer insulating film 43. The third interlayer insulating film 43 is formed of, for example, NSG. In addition, in the third interlayer insulating film 43, silicate glass, such as PSG, BSG, BPSG, or the like, silicon nitride or silicon oxide may be used. The surface of the third interlayer insulating film 43 is subjected to a planarizing process, such as a CMP process, or the like, in the same manner as the second interlayer insulating film 42.

The pixel electrodes 9a (whose outline is shown by broken lines 9a″ in FIG. 5) are respectively disposed in the two-dimensionally divided pixel regions, and the data lines 6a and the scanning lines 11a are disposed in a matrix at interfaces between the pixel electrodes 9a (see FIGS. 4 and 5). In addition, the pixel electrode 9a is made of a transparent conductive film, such as, for example, ITO (indium tin oxide).

The pixel electrode 9a is electrically connected to the extending portion of the capacitor electrode 300 through the contact hole 85 which passes through the interlayer insulating film 43 (see FIG. 7).

As described above, the extending portion of the capacitor electrode 300 and the interlayer layer 600 are electrically connected to each other through the contact hole 84, and the interlayer layer 600 and the highly doped drain region 1e of the TFT 30 are electrically connected to each other through the contact hole 83. That is, the pixel electrode 9a and the highly doped drain region 1e of the TFT 30 relay the relay layer 600 and the extending portion of the capacitor electrode 300 and connect them to each other. In addition, an alignment film 16, which is subjected to a predetermined alignment treatment, such as a rubbing process or the like, is provided on the pixel electrode 9a.

In this manner, the pixel portion of the TFT array substrate 10 side is constructed.

Additionally, a counter electrode 21 is provided on the entire surface of the facing surface of the counter substrate 20 opposite to the TFT array substrate, and an alignment film 22 is provided on the counter substrate (lower side of the counter electrode 21 in FIG. 7). Similar to the pixel electrode 9a, the counter electrode 21 is made of a transparent conductive film, such as, for example, an ITO film or the like. In addition, in order to prevent a light leak current from being generated in the TFT 30, a light shielding film 23 is provided between the counter substrate 20 and the counter electrode 21 so as to cover at least a region opposite to the TFT 30.

The liquid crystal layer 50 is provided between the TFT array substrate 10 and the counter substrate 20 with the above-mentioned structures. The liquid crystal layer 50 is formed by injecting liquid crystal in a space that is formed by sealing the peripheral portions of the substrates 10 and 20 with a sealant. In a state in which an electric field is not applied between the pixel electrode 9a and the counter electrode 21, the liquid crystal layer 50 enters a predetermined alignment state by means of the alignment films 16 and 22 having been subjected to an alignment treatment, such as a rubbing process.

As shown in FIGS. 4 and 5, the above-mentioned structure of the pixel portion is the same as the respective pixel portions. In the above-mentioned image display region 10a (see FIG. 1), the above-mentioned pixel portions are periodically formed. In the meantime, in this liquid crystal device, the driving circuits, such as the scanning line driving circuit 104, the data line driving circuits 101 or the like, are formed in the peripheral regions of the image display region 10a, as having been described with reference to FIGS. 1 and 2.

Method of Manufacturing Electro-Optical Device

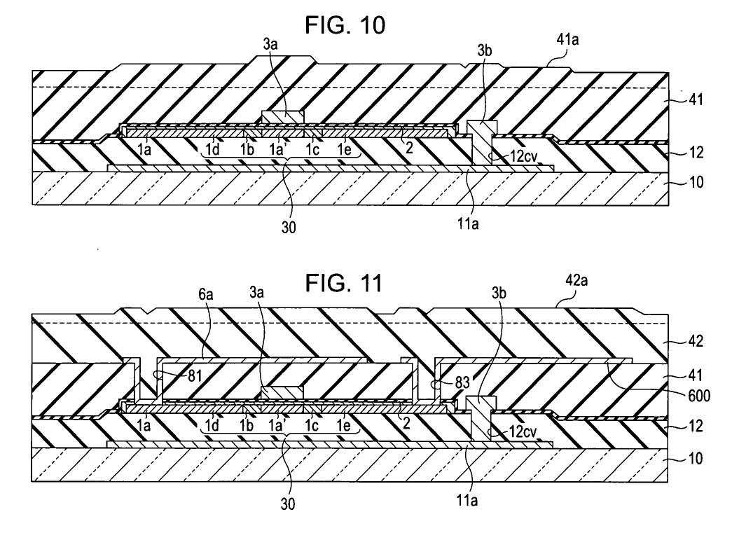

Next, in accordance with an exemplary embodiment of the invention, a method of manufacturing an electro-optical device will be described with reference to FIGS. 8 to 13. FIGS. 10 to 13 are diagrams sequentially illustrating the laminated structure of the electro-optical device in each of the manufacturing processes in accordance with the cross-section corresponding to FIG. 7. In this case, only the forming processes of the scanning line, the TFT, the data line, the storage capacitor, and the pixel electrode, which are main portions of the liquid crystal device according to the present embodiment, will be mainly described in detail.

As shown in FIG. 10, first, the scanning lines 11a are formed on the TFT array substrate 10. Next, the base insulating film 12 is formed on the entire surface of the TFT array substrate 10. At this time, the base insulating film 12 may be subjected to a planarizing process, such as, for example, a CMP process, a fluidization process (reflowing process), or the like. Then, the TFTs 30 are formed in regions corresponding to intersections between the scanning lines 11a and the data lines 6a which will be described in detail below. In the process of forming the TFT 30, a general semiconductor integration technology may be used. Then, a precursor film 41a of the first interlayer insulating film 41 is formed on an entire surface of the TFT array substrate 10. On the surface of the precursor film 41a, unevenness is generated due to the TFT 30 of the lower layer side or the like. Accordingly, the precursor film 41a is formed so as to have a large thickness. Then, the precursor film 41a is cut at a location of the dotted line in the drawing by means of, for example, a CMP process, and the surface of the precursor film 41a is planarized. As a result, the first interlayer insulating film 41 is obtained. In addition, as the planarizing process, a fluidization process (reflowing process), a spin coating process, or the like may be used.

Then, in a process illustrated in FIG. 11, an etching process is performed at a predetermined location of the surface of the first interlayer insulating film 41, a contact hole 81 having a depth capable of reaching the highly doped source region 1d and a contact hole 83 having a depth capable of reaching the highly doped drain region 1e are formed. Then, a conductive light shielding film is laminated in a predetermined pattern, thereby forming the data line 6a and the interlay layer 600. The data line 6a is formed so as to partially cover the channel region 1a of the TFT 30, and connected to the highly doped source region 1d through the contact hole 81. FIG. 8 illustrates another exemplary embodiment of the present embodiment. As shown in FIG. 8, in the data line 6a, first, as the low-reflective portion 61, metal of a material whose reflectance is smaller than that of an Al film, or barrier metal may be laminated, and then an Al film or the like may be laminated as the main body portion 60. Alternatively, as illustrated in FIG. 9, in yet another embodiment of the present embodiment, in the data line 6a, first, as the lower low-reflective portion 63, metal of a material whose reflectance is smaller than that of an Al film, or barrier metal may be laminated, then an Al film or the like may be laminated as the main body portion 60, and as the upper low-reflective portion 63, metal of a material whose reflectance is smaller than that of an Al film, or barrier metal may be laminated.

The relay layer 600 is connected to the highly doped drain region 1e through the contact hole 83. Then, the precursor film 42a of the second interlayer insulating film 42 is formed on the entire surface of the TFT array substrate 10. On the surface of the precursor film 42a, unevenness is generated due to the TFT 30, the data line 6a, and the contact holes 81 and 83 of the lower layer side. Accordingly, the precursor film 42a is formed so as to have a large thickness. Then, the precursor film 42a is cut at a location of the dotted line in the drawing by means of, for example, a CMP process, and the surface of the precursor film 42a is planarized, which results in obtaining the second interlayer insulating film 42.

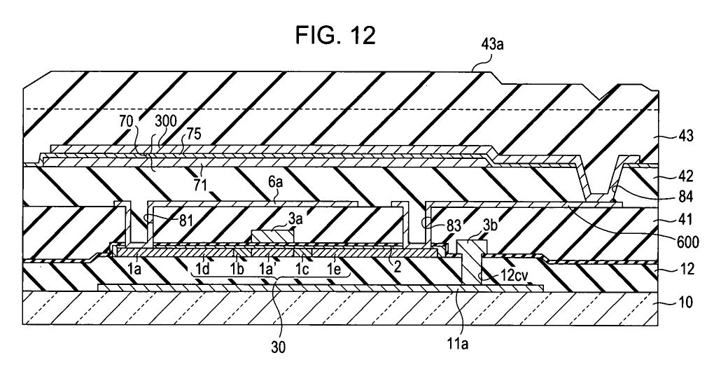

Then, in a process illustrated in FIG. 12, a conductive light shielding film is laminated on a predetermined region of the surface of the second interlayer insulating film 42 including a region opposite to the channel region 1a′, thereby forming a lower electrode 71. Then, the dielectric film 75 is formed in a non-opening region on the TFT array substrate 10. Then, an etching process is performed at a predetermined location of the surface of the dielectric film 75, a contact hole 84 having a depth capable of reaching the intermediate layer 600 is formed. Next, a conductive light shielding film is laminated on a predetermined region of the surface of the second interlayer insulating film 42 including a region opposite to the channel region 1a′, thereby forming a capacitor electrode 300. Then, the precursor film 43a of the third interlayer insulating film 43 is formed on the entire surface of the TFT array substrate 10. On the surface of the precursor film 43a, unevenness is generated due to the storage capacitor 70 or the contact hole 84. Accordingly, the precursor film 43a is formed so as to have a large thickness, is then cut at a location of the dotted line in the drawing by means of, for example, a CMP process, and the surface of the precursor film 43a is planarized, which results in obtaining the third interlayer insulating film 43.

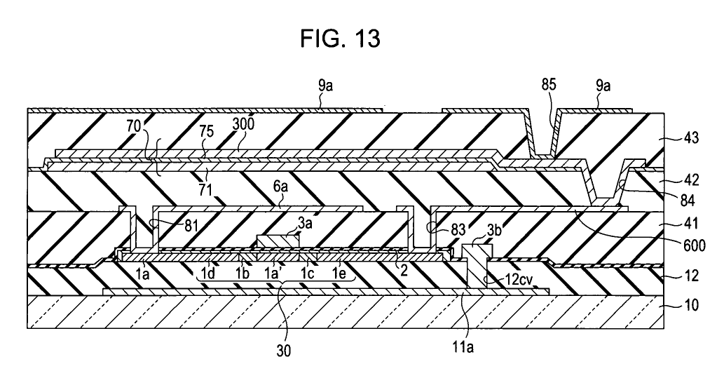

Next, in the process illustrated in FIG. 13, an etching process is performed at a predetermined location of the surface of the third interlayer insulating film 43, and a contact hole 85 with a depth capable of reaching the extending portion of the capacitor electrode 300 is formed. Then, the pixel electrode 9a is formed at a predetermined location of the surface of the third interlayer insulating film 43. At this time, although the pixel electrode 9a is formed even in the contact hole 85, since a diameter of the contact hole 85 is increased, the coverage becomes excellent.

According to the above exemplary method, since the data line 6a made of the conductive light shielding film is formed on the first interlayer insulating film 41 having subjected to the planarizing process, the light leak current in the TFT 30 may be reduced, the contrast ratio can be improved, and a high quality image display can be achieved. Further, since the laminated structure on the TFT array substrate 10 is relatively simple, the manufacturing process can be simplified, and the manufacturing yield can be improved.

Electronic Apparatus

Next, in accordance with another exemplary embodiment of the invention, examples will be described in which the liquid crystal device in accordance with the above-mentioned electro-optical device, is applied to various electronic apparatuses.

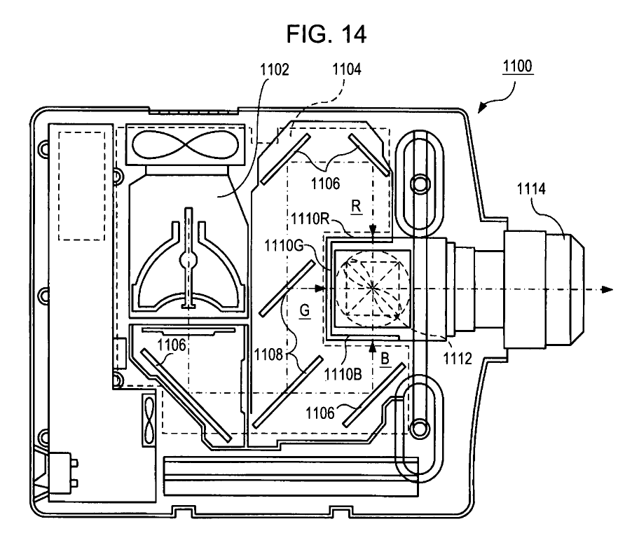

First, a projector using the above-mentioned liquid crystal device as a light valve will be described. FIG. 14 is a plan view illustrating an example of a structure of a projector. As shown in FIG. 14, a lamp unit 1102, which is composed of a white light source, such as a halogen lamp or the like, is provided in a projector 1100. The light emitted from the lamp unit 1102 is divided into three primary colors of RGB by means of four mirrors 1106 and two dichroic mirrors 1108 which are disposed in a light guide 1104, and then incident on liquid crystal panels 1110R, 1110B, and 1110G serving as light valves corresponding to the three primary colors.

The structure of each of the liquid crystal panels 1110R, 1110B, and 1110G is the same as the above-mentioned liquid crystal device. The liquid crystal panels 1110R, 1110B, and 1110G are driven with primary color signals for RGB which are supplied from an image signal processing circuit. In addition, the light modulated by these liquid crystal panels is incident on a dichroic prism 1112 in three directions. In the dichroic prism 1112, the light for R and B is refracted at an angle of 90 degrees while the light for G propagates straightly. Accordingly, the images of the respective colors are synthesized, so that a color image is projected onto a screen or the like through a projection lens 1114.

In this embodiment, if focusing on display images by the respective liquid crystal panels 1110R, 1110G, and 1110B, the display image by the liquid crystal panel 1110G needs to be inversed in a horizontal direction with respect to the display images by the liquid crystal panels 1110R and 1110B.

In addition, since the light corresponding to the respective primary colors of RGB is incident on the liquid crystal panels 1110R, 1110G, and 1110B by means of the dichroic mirror 1108, color filters do not need to be provided.

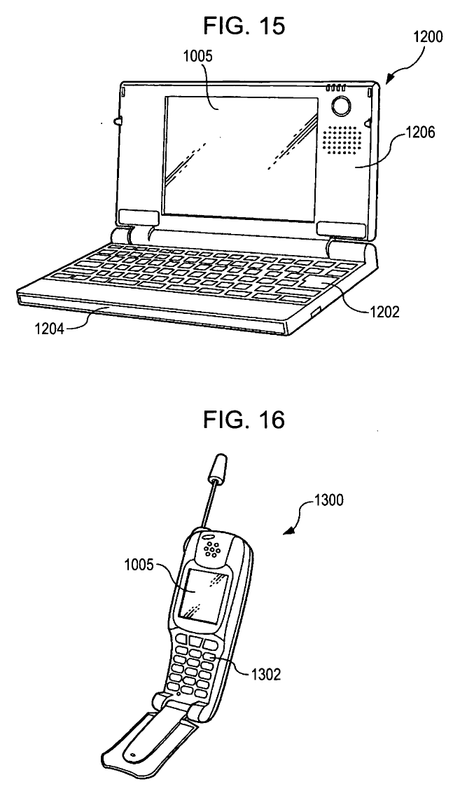

Next, an example will be described in which the above-mentioned liquid crystal device is applied to a mobile-type personal computer. FIG. 15 is a perspective view illustrating a structure of a personal computer. In FIG. 15, a computer 1200 includes a main body portion 1204 with a keyboard 1202, and a liquid crystal display unit 1206. This liquid crystal display unit 1206 is constructed by additionally supplying a backlight on a rear surface of the above-mentioned liquid crystal device 1005.

Further, an example in which the above-mentioned liquid crystal device is applied to a cellular phone will be described. FIG. 16 is a perspective view illustrating the structure of the cellular phone. In FIG. 16, a cellular phone 1300 includes a plurality of operation buttons 1302, and a reflective liquid crystal device 1005. In this reflective liquid crystal device 1005, a front light is provided on a front surface of the liquid crystal device, if necessary.

In addition to the electronic apparatuses having been described with reference to FIGS. 14 to 16, examples of the electronic apparatuses may include a liquid crystal television, a view-finder-type or monitor-direct-view video tape recorder, a car navigation device, a pager, an electronic note, an electronic calculator, a word processor, a workstation, a video phone, a POS terminal, an apparatus with a touch panel, or the like.

In addition to the liquid crystal devices according to the above-mentioned embodiments, the invention may be applied to a reflective liquid crystal device (LCOS) in which elements are formed on a silicon substrate, a plasma display (PDP), a field emission display (FED and SED), an organic EL display, or the like.

The invention is not limited to the above-mentioned embodiments, and various changes and modifications may be made without departing from the spirit or scope of the invention which is readable from the appended claims and the specification. The scope of the invention is to be determined only by the appended claims and their equivalents. In addition, an electro-optical device accompanied with various changes and modifications, any electronic apparatus having this electro-optical device, and a method of manufacturing the electro-optical device are all, for example, within the technical range of the present invention.

What is claimed is:

1. An electro-optical device comprising:
a substrate,
a plurality of data lines and a plurality of scanning lines that extend so as to cross each other;
a plurality of thin film transistors each having a channel region, each of the thin film transistors being disposed closer to the substrate than the data lines;
a first interlayer insulating film which is laminated on the thin film transistor and has been subjected to a planarizing process;
a plurality of storage capacitors, each storage capacitor being disposed at least partially opposite of the channel region of the thin film transistor in plan view, and disposed further from the substrate than the data lines, and each storage capacitor having a structure in which a fixed potential side electrode, a dielectric film, and a pixel potential side electrode are sequentially laminated as referenced from the substrate;
a plurality of pixel electrodes, each pixel electrode being disposed further from the substrate than each storage capacitor, and being electrically connected to the pixel potential side electrode and the thin film transistor; and
each of the data lines comprising a conductive light shielding film and formed so as to at least partially cover the channel region of each of the thin film transistors in plan view.

2. The electro-optical device according to claim 1,
wherein the planarizing process of the first interlayer insulating film includes a CMP process.

3. The electro-optical device according to claim 1,
wherein the first interlayer insulating film contains a first fluidization material that fluidizes at a predetermined temperature, and
the planarizing process of the first interlayer insulating film includes a fluidization process for fluidizing the first fluidization material.

4. The electro-optical device according to claim 1,
wherein a second interlayer insulating film has been subjected to a second planarizing process and is laminated on at least one location among the data lines, the storage capacitors, and the pixel electrodes.

5. The electro-optical device according to claim 1,
wherein each of the data lines includes:
a main body portion; and
a low-reflective portion, the low-reflective portion being disposed at a side of the data line that faces the channel region of the thin film transistor, and the low-reflective portion having a lower reflectance than the main body portion.

6. The electro-optical device according to claim 1,
wherein each of the data lines includes:
a main body portion;
a lower low-reflective portion disposed at a side of the main body portion that faces the channel region of the thin film transistor, the lower low-reflective portion having a lower reflectance than the main body portion; and
an upper low-reflective portion disposed at a side of the main body portion that faces away from the channel region of the thin film transistor, the upper low-reflective portion having a lower reflectance than the main body portion.

7. The electro-optical device according to claim 1, further comprising:
a lower light shielding film that is disposed closer to the substrate than the thin film transistors; and
a base insulating film that is laminated on the lower light shielding film and subjected to a second planarizing process.

8. The electro-optical device according to claim 7,
wherein the second planarizing process for the base insulating film comprises a CMP process.

9. The electro-optical device according to claim 7,
wherein the base insulating film contains a second fluidization material that fluidizes at a predetermined temperature, and
the second planarizing process for the base insulating film being a fluidization process for fluidizing the second fluidization material.

10. An electronic apparatus comprising the electro-optical device according to claim 1.

11. An electro-optical device comprising:
a substrate;
a data line for supplying an image signal;
a thin film transistor having a channel region, the thin film transistor being formed above the substrate at a distance from the substrate that is shorter than a distance from the substrate to the data line, the data line being formed in a region that at least partially covers, from a plan view, the channel region of the thin film transistor.
a first interlayer insulating film which is disposed on the thin film transistor and has been subjected to a planarizing process;
a storage capacitor which is disposed at a distance from the substrate that is greater than the distance from the substrate to the data line, the storage capacitor having a capacitor electrode;
a pixel electrode being disposed at a distance from the substrate that is greater than the distance from the substrate to the storage capacitor, the pixel electrode being electrically connected to the capacitor electrode and the thin film transistor.

12. The electro-optical device according to claim 11, wherein the planarizing process of the first interlayer insulating film comprises a CMP process.

13. The electro-optical device according to claim 11, wherein the data line is formed on the first interlayer insulating film.

14. The electro-optical device according to claim 11,
wherein the first interlayer insulating film contains a first fluidization material that fluidizes at a predetermined temperature, and
the planarizing process of the first interlayer insulating film comprises a fluidization process for fluidizing the first fluidization material.

15. The electro-optical device according to claim 11,
wherein the data line includes a conductive light shielding film, the conductive light shielding film comprising:
a main body portion having a reflectance; and
a low-reflective portion formed on the main body portion opposite of the channel region of the thin film transistor, the low-reflective portion having a reflectance that is lower than the reflectance of the main body portion.

16. The electro-optical device according to claim 11,
wherein the data line includes a conductive light shielding film, the conductive light shielding film comprising:
a main body portion having a main body reflectance;
a first low-reflective portion that is formed on a side of the main body portion opposite of the channel region, the first low-reflective portion having a first reflectance, the first reflectance being lower than the main body reflectance; and
a second low-reflective portion that is formed on the other side of the main body portion opposite of the side of the first low-reflective portion, the second low-reflective portion having a second reflectance, the second reflectance being lower than the main body portion reflectance.

17. The electro-optical device according to claim 11, further comprising:
a lower light shielding film that is disposed at a distance from the substrate that is shorter than the distance from the substrate to the thin film transistor; and
a base insulating film that is disposed on the lower light shielding film and subjected to a planarizing process.

18. The electro-optical device according to claim 16,
wherein the planarizing process for the base insulating film is a CMP process.

19. The electro-optical device according to claim 17,
wherein the base insulating film contains a second fluidization material that fluidizes at a predetermined temperature, and
the planarizing process for the base insulating film includes a fluidization process for fluidizing the second fluidization material.

20. A method of manufacturing an electro-optical device, the electro-optical device including: a substrate, a plurality of data lines and a plurality of scanning lines that extend so as to cross each other; a plurality of top-gate-type thin film transistors, and a first interlayer insulating film interposed between the thin film transistors and the data lines; a plurality of storage capacitors each of which is disposed above the data lines, and a plurality of pixel electrodes each of which is disposed above the storage capacitors, the method comprising:
forming the thin film transistors such that a channel region of the thin film transistors, when viewed in plan view, is covered by the data lines at a region corresponding to an intersection between the data lines and the scanning lines;
forming the first interlayer insulating film on the thin film transistors;
subjecting the first interlayer insulating film to a planarizing process;
forming the data lines on the first interlayer insulating film, the data lines being comprised of a conductive light shielding film;
forming the storage capacitors, when taken from plan view, in a region opposite of the channel region of the thin film transistors such that a fixed potential side electrode, a dielectric film, and a pixel potential side electrode are sequentially laminated on the data lines; and
forming the pixel electrodes on the storage capacitors for each pixel provided so as to correspond to the data lines and the scanning lines on the substrate in plan view, the pixel electrodes being electrically connected to the thin film transistors and the pixel potential side electrodes.
